(19) United States
(12) Patent Application Publication
(10) Pub. No.: US 2010/0119351 A1
(43) Pub. Date: May 13, 2010

(54) Method and system for venting load lock chamber to a desired pressure

(75) Inventors: Xiao-Jun Liu, Camas, WA (US); Ron Hou, Camas, WA (US)

Correspondence Address: DUANE MORRIS LLP - San Diego, 101 WEST BROADWAY, SUITE 900, SAN DIEGO, CA, 92101-8285, US

(73) Assignee: WaferTech, LLC

(21) Appl. No.: 12/291,794

(22) Filed: Nov. 13, 2008

(51) Int. Cl. H01L 21/677

(52) U.S. Cl. 414/805; 414/217

(57) ABSTRACT

A system and method for reducing particulate contamination during the loading and unloading of semiconductor substrates into a load lock chamber of a semiconductor processing tool provides one or more pressure sensors that measure the actual ambient pressure in the fabrication facility or within a discrete environment within the fabrication facility and determine a crossover pressure to be used to open a load lock chamber door after the load lock is vented. The crossover pressure is determined by an input indicating a relationship between the desired crossover pressure and a detected ambient pressure. The crossover pressure may be identical to, greater than, or less than the measured ambient pressure. The ambient pressure may be measured on an ongoing or real-time basis.

### FIELD OF THE INVENTION

The present invention relates, most generally, to semiconductor manufacturing systems and methods. More particularly, the invention relates to a method and system for venting a load lock chamber to a desired crossover pressure.

### BACKGROUND

Today's rapidly advancing semiconductor manufacturing industry involves highly-precise operations performed upon semiconductor substrates and extremely miniaturized features formed on the semiconductor devices produced on the semiconductor substrates. In order to accurately and reliably produce the highly-miniaturized features and produce functional and reliable devices, contamination sources must be eliminated from the processing environment because even one contaminating particle can destroy the functionality of a device.

The semiconductor fabrication process involves a number of processing operations carried out in different processing tools. Many of these tools are high vacuum processing tools and when the semiconductor substrates undergoing the fabrication process are transferred from one high vacuum processing tool to another, they are transferred into or out of the associated load lock chamber of the high vacuum processing tool. In order to open the load lock door to the outside and transfer substrates into or out of the load lock chamber, the load lock chamber is vented to atmosphere, according to conventional technology in which the outside environment is generally considered to be at atmosphere, i.e. at 760,000 mT.

Particulate contamination associated with breaking vacuum, i.e., venting the load lock chamber and opening the load lock chamber door to the fabrication facility environment, can destroy semiconductor devices, especially as device features continue to shrink and the sensitivity to particle damage increases. If the venting process used to increase the load lock chamber pressure to or near atmospheric pressure is too turbulent, particle contamination may result. The crossover pressure level in the load lock when the load lock door is opened to the environment, is also very important to particle generation. For example, if the crossover pressure in the load lock is too low when the load lock door is opened to the fabrication area environment, dirty outside air could potentially stream back into the load lock and the tool and the resulting particles may cause substantial defects to the substrates. Conversely, if the crossover pressure maintained in the load lock is too high when the load lock door is opened to the environment, the resulting outward burst could similarly cause contaminating particle generation.

It would therefore be desirable to minimize any turbulence and particle generation associated with opening the load lock door to the fabrication area environment.

### SUMMARY OF THE INVENTION

To address these and other needs, and in view of its purposes, one aspect of the invention provides a method for venting a load lock chamber in a semiconductor processing tool. The method includes detecting ambient pressure outside the tool, determining a desired load lock crossover pressure based on the detected ambient pressure and purging the load lock chamber with an inert gas until the desired load lock crossover pressure is achieved and the load lock chamber stabilizes at the desired load lock crossover pressure. The method then provides for opening an external load lock door after the load lock chamber stabilizes at the desired load lock crossover pressure.

According to another aspect, the invention provides a system for venting a load lock chamber of a semiconductor processing tool. The system includes a pressure sensor capable of detecting ambient pressure outside the semiconductor tool, means for determining a desired load lock crossover pressure based on the detected ambient pressure, and a venting system capable of purging the load lock chamber with an inert gas until the desired load lock crossover pressure is achieved and stabilizes in the load lock chamber. The system further includes an actuator capable of opening an external load lock door responsive to the load lock pressure stabilization in the load lock chamber.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, dimensions of the various features may be arbitrarily expanded or reduced for clarity. Like numerals denote like features throughout the specification and drawing.

FIG. 1 is a front view illustrating a semiconductor processing tool with a load lock chamber disposed in an exemplary mini-environment in a semiconductor fabrication production area;

FIG. 2 is a flow chart illustrating one exemplary sequence of events for carrying out an aspect of the invention; and

FIG. 3 is a flow chart illustrating another exemplary sequence of events for carrying out an aspect of the invention.

### DETAILED DESCRIPTION

The present invention provides a method and system that reduces particle contamination when a load lock door is opened to the fabrication area environment, by achieving and maintaining a crossover pressure in the load lock chamber that is equal to the pressure in the fabrication environment, or represents a desired pressure difference between the load lock chamber and the fabrication area environment, when the load lock door is open. The system and method provide for accurately monitoring the pressure in the fabrication area environment or mini-environment on an ongoing or real-time basis even as the ambient pressure in the fabrication area environment drifts from atmosphere, i.e. 760,000 mT. It has been found that the ambient pressures throughout the semiconductor fabrication area may vary, sometimes significantly, from 760,000 mT. The fluctuations may be fluctuations in time and may result from changing weather, for example. The ambient pressure within the semiconductor fabrication area may also vary spatially within the semiconductor fabrication area, such as in mini-environments that may be produced when certain portions of the fabrication area are located under laminar flow hoods, or subject to other environment-affecting factors.

The invention provides for detecting ambient pressure outside of the semiconductor processing tool and determining a desired crossover pressure based on the detected ambient pressure, purging the load lock chamber until the desired crossover pressure is achieved in the load lock chamber, and opening the external load lock door after the load lock chamber has stabilized at the desired crossover pressure.

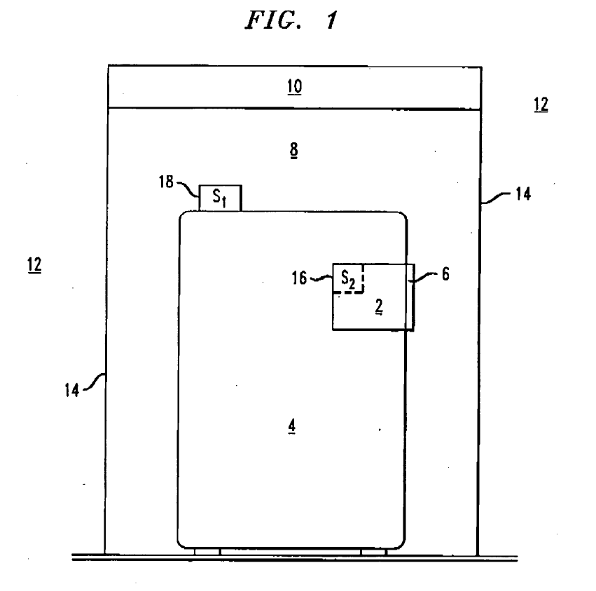

FIG. 1 shows a load lock chamber in conjunction with a semiconductor processing tool. Load lock chamber 2 forms part of semiconductor tool 4 and allows for semiconductor substrates, i.e. wafers, to be loaded into semiconductor tool 4 through load lock door 6. In some embodiments, an automated external substrate transport system may be directly coupled to or near load lock chamber 2. Semiconductor tool 4 may be any of various processing equipment tools used in the semiconductor manufacturing industry. Semiconductor tool 4 may be a high-vacuum tool in which substrates are processed in near-vacuum conditions, or at very low pressures. Semiconductor tool 4 may be an etching tool, a deposition tool, a photolithography tool, a metrology tool, a cleaning system, an analytical tool or any of various other tools used in semiconductor device fabrication industry.

After the semiconductor substrates are introduced to load lock chamber 2, an additional door or doors, in conjunction with internal transport mechanisms, transfer the substrates internally from load lock chamber 2 to other portions of semiconductor tool 4 for processing. Conventional pumping and venting systems may be used in conjunction with load lock chamber 2. In the illustrated embodiment, semiconductor tool 4 is located within optional mini-environment 8 which is a discrete environment within environment 12 of a semiconductor fabrication area. According to other exemplary embodiments, semiconductor tool 4 may be situated within environment 12 and not within any mini-environment within the fabrication area. According to one exemplary embodiment, mini-environment 8 may be produced by laminar flow hood 10 and defined by walls 14 which may be rigid impermeable walls, flexible plastic sheets, permeable dividers or other conventional devices used to produce mini-environments within a semiconductor fabrication area.

In the illustrated embodiment, pressure sensor 16 is disposed within load lock chamber 2 and pressure sensor 18 is located external to semiconductor tool 4. It should be noted that additional pressure sensors may be used in other exemplary embodiments and in particular that the external pressure sensor 18 need not be in contact with semiconductor tool 4 and may be disposed in various other locations within mini-environment 8 or within environment 12 of the semiconductor fabrication area. According to yet another exemplary embodiment, external pressure sensor 18 may not be used. Pressure sensors 16 and 18 may be any of various suitable conventional pressure sensors available in the art and capable of detecting both high-vacuum pressures and also pressures in the range of atmospheric pressure.

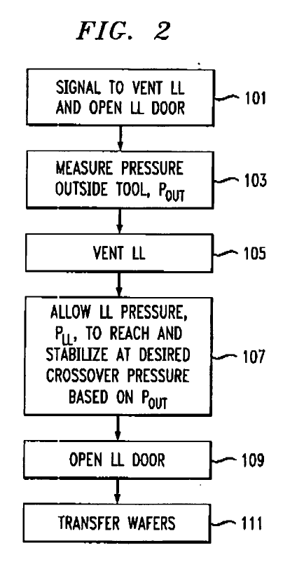

FIG. 2 illustrates a flow chart that shows an exemplary sequence of operations according to an aspect of the invention. At step 101, a signal is sent to vent the load lock chamber and open the load lock door, typically to load or unload substrates to be or which have been processed. In other exemplary embodiments, the signal may be sent to vent the load lock chamber and open the load lock door for other purposes such as for testing or maintenance procedures. The signal may be sent automatically, such as when processing of substrates in semiconductor tool 4 is complete and it is desired to unload the wafers from semiconductor tool 4 via load lock chamber 2, or when an external delivery of substrates arrives at semiconductor tool 4 and is acknowledged and queued for being processed in the tool. Such signals may alternatively be sent manually.

At step 103, the pressure outside the semiconductor tool, Pₒᵤₜ, is measured. This may be accomplished using conventional pressure detectors/sensors such as pressure sensor 18 shown in FIG. 1 or various other suitable pressure detectors that may be located proximally or distally external to semiconductor tool 4 and load lock chamber 2. In various exemplary embodiments, multiple pressure sensors may be used and the pressure measured by each of the pressure sensors averaged to determine a mean Pₒᵤₜ. According to the exemplary embodiment in which the outside pressure is sensed responsive to a signal requesting the load lock chamber to be opened, i.e. step 101, a real-time pressure is obtained. In one embodiment, pressure sensor 18 may detect the ambient pressure Pₒᵤₜ substantially continuously and the most recently recorded measured pressure will be used as Pₒᵤₜ. In various embodiments Pₒᵤₜ may be stored in a memory which may be in a processor, and referenced for calculation in subsequent step 107.

At step 105, the load lock chamber is vented responsive to the signal sent at step 101. Conventional systems may be used to vent the load lock chamber such as by purging with nitrogen or another inert gas. Various suitable purging/venting systems are available in the art and may be used. The pressure in the load lock chamber is increased and, at step 107, the load lock pressure, P_{LL}, is allowed to reach and stabilize at a desired crossover pressure that is determined based on Pₒᵤₜ. The crossover pressure is the pressure in load lock chamber 2 at which load lock door 6 is opened. The desired crossover pressure may be the same or different than Pₒᵤₜ, the pressure measured outside semiconductor tool 4 and which may be saved in memory. In one exemplary embodiment, the desired crossover pressure will be a pressure identical to the detected pressure outside producing no pressure gradient when load lock door 6 is opened and in other exemplary embodiments, the desired crossover pressure may be up to 100,000 millitorr greater than or less than the outside detected pressure, Pₒᵤₜ. According to one exemplary embodiment, the crossover pressure, i.e. the pressure at which the load lock chamber is allowed to stabilize before load lock chamber door 6 opens, may be 20,000-30,000 millitorr greater than Pₒᵤₜ and in yet another exemplary embodiment, the crossover pressure may be 20,000-30,000 millitorr less than Pₒᵤₜ.

After the load lock chamber achieves and stabilizes at the desired crossover pressure, the load lock door is opened at step 109, and the transfer of wafers into or out of the load lock chamber from outside semiconductor tool 4, may take place at step 111.

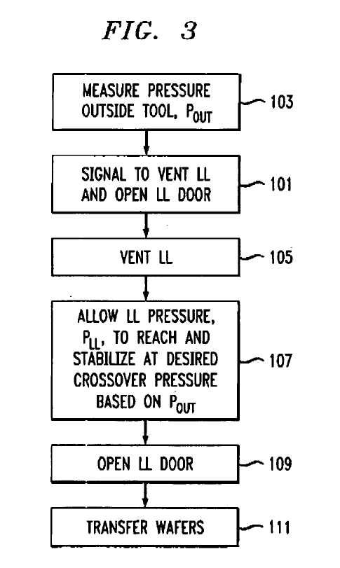

According to the exemplary sequence in FIG. 3, the outside pressure, Pₒᵤₜ, is detected prior to the signal sent at step 101 to vent the load lock chamber and open the load lock door. In one embodiment, pressure sensor 18 may detect the ambient pressure Pₒᵤₜ substantially continuously and the most recently recorded measured pressure value will be recorded and used as Pₒᵤₜ. According to this exemplary embodiment, Pₒᵤₜ may be recorded and stored in memory or a controller or processor and accessed when the signal is sent at step 101 to vent the load lock chamber and open the load lock door. According to another exemplary embodiment, a single sensor such as pressure sensor 16 disposed within load lock chamber 2, may be used. According to this embodiment, when load lock door 6 is opened to the environment, the pressure Pₒᵤₜ is measured by pressure sensor 16. This may take place, for example, during the loading of a first production run. According to one exemplary embodiment, the signal sent at step 101 may be a signal to vent the load lock chamber at the conclusion of the same first production run or for a second or subsequent production run. According to this exemplary embodiment, the load lock chamber is vented at step 105 responsive to the signal sent at step 101 and the stored value of Pₒᵤₜ is accessed and used to determine the desired crossover pressure at step 107. At step 107, the load lock pressure, P_{LL}, is allowed to achieve and stabilize at the desired crossover pressure based on Pₒᵤₜ. According to this exemplary embodiment, the Pₒᵤₜ value used may be the most recently measured Pₒᵤₜ value at step 103. Once the crossover pressure is achieved, the load lock door is opened at step 109 and wafer transfer into or out of the load lock may take place at step 111.

According to the aforementioned exemplary embodiments, the desired crossover pressure, P_{crossover}, may be determined based on Pₒᵤₜ. Conventional input means may be used to receive an input and determine a crossover pressure to be achieved and stabilized in the load lock before door opening, by comparison to Pₒᵤₜ. The input is indicative of a mathematical relationship between Pₒᵤₜ and the desired load lock pressure, P_{crossover}. The input may indicate that the desired crossover pressure, P_{crossover}, equals outside pressure Pₒᵤₜ. In one embodiment P_{crossover} may be expressed as a percentage less than or greater than Pₒᵤₜ, e.g., P_{crossover}=Pₒᵤₜ×1.01. According to another exemplary embodiment, the crossover pressure may be expressed as a pressure differential. For example, the input may be “plus 20,000 millitorr” indicating that the desired crossover pressure is the measured outside pressure Pₒᵤₜ, plus 20,000 millitorr, i.e. “P_{crossover}=Pₒᵤₜ+20,000 millitorr.” For example, if Pₒᵤₜ measured at step 101 equals 750,000 millitorr and the input for desired crossover pressure is “plus 20,000 millitorr” the crossover pressure that the load lock is allowed to achieve and stabilize at, i.e. the crossover pressure, before the door may open, will be 770,000 millitorr. Conversely, if the desired crossover pressure is expressed as: P_{crossover}=Pₒᵤₜ−10,000 millitorr, the crossover pressure, according to this exemplary embodiment, will be 740,000 millitorr.

According to various exemplary embodiments, conventional components may be used to carryout the aforementioned method. For example, a conventional memory may be used to store either or both of the measured Pₒᵤₜ and the input mathematical relationship between Pₒᵤₜ and P_{crossover}. A processor with input means may be used to receive the desired crossover pressure relationship and conventional processing means may be used to derive the crossover pressure based on the input mathematical relationship between Pₒᵤₜ and P_{crossover} once Pₒᵤₜ is detected/measured. The system may further include a controller that provides P_{crossover} to the load lock chamber and directs the load lock door to open when P_{crossover} is achieved. The system may further include conventional mechanical features such as a conventional actuator that opens the load lock door once the desired crossover pressure has been achieved.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method for venting a load lock chamber of a semiconductor processing tool, comprising:
detecting ambient pressure outside said semiconductor processing tool;
determining a desired load lock crossover pressure based on said detected ambient pressure;
purging said load lock chamber with an inert gas until said load lock chamber achieves and stabilizes at said desired load lock crossover pressure; and
opening an external load lock door after said load lock chamber stabilizes at said desired load lock crossover pressure.

2. The method as in claim 1, wherein said desired load lock crossover pressure equals said detected ambient pressure.

3. The method as in claim 1, wherein said desired load lock crossover pressure comprises a pressure of about 20,000-30,000 millitorr greater than said detected ambient pressure.

4. The method as in claim 1, wherein said desired load lock crossover pressure comprises a pressure that is about 1 percent greater than said detected ambient pressure, in millitorr.

5. The method as in claim 1, wherein said determining comprises a processor performing a mathematical calculation using said detected ambient pressure.

6. The method as in claim 1, wherein said determining comprises inputting to a processor a mathematical relationship between said desired load lock crossover pressure and said detected ambient pressure and calculating said desired load lock crossover pressure therefrom.

7. The method as in claim 1, wherein said determining comprises accessing said detected ambient pressure stored in a memory of a processor; and further comprising transporting semiconductor wafers through an external opening formed when said load lock door is opened.

8. The method as in claim 1, wherein a first external sensor is used for said detecting ambient pressure and a second internal sensor is used for determining when said load lock chamber achieves and stabilizes at said desired load lock crossover pressure.

9. The method as in claim 1, further comprising delivering a signal to said load lock chamber to vent and open said load lock door and wherein said detecting ambient pressure is performed responsive to said delivering.

10. The method as in claim 1, wherein a pressure sensor is disposed in said load lock chamber and said detecting ambient pressure comprises measuring said ambient pressure using said pressure sensor when said load lock chamber is opened.

11. The method as in claim 10, wherein said detecting ambient pressure takes place when said load lock door is opened during loading of a first run and said purging said load lock chamber with an inert gas until said load lock chamber achieves and stabilizes at said desired load lock crossover pressure, takes place during one of unloading of said first run, and loading of a subsequent run.

12. The method as in claim 1, wherein said measuring ambient pressure comprises said ambient pressure being a pressure in a discrete environment within a semiconductor fabrication production facility.

13. The method as in claim 1, wherein said detecting ambient pressure takes place substantially continuously, and said determining determines said desired load lock crossover pressure based on a most recently detected value of said ambient pressure.

14. A system for venting a load lock chamber of a semiconductor processing tool, said system comprising:
a pressure sensor capable of detecting ambient pressure outside said semiconductor processing tool;
means for determining a desired load lock crossover pressure based on said detected ambient pressure;
a venting system capable of purging said load lock chamber until said desired load lock crossover pressure is achieved and stabilizes in said load lock chamber; and
an actuator capable of opening an external load lock door responsive to said desired load lock crossover pressure stabilization in said load lock chamber.

15. The system as in claim 14, wherein said means for determining a desired load lock crossover pressure include input means for receiving a mathematical relationship between said measured ambient pressure and said desired load lock crossover pressure.

16. The system as in claim 15, wherein said mathematical relationship provides that said desired load lock crossover pressure is one of the same as and within a range of about 20,000-30,000 millitorr greater than, said detected ambient pressure.

17. The system as in claim 14, wherein said ambient pressure comprises a pressure in a discrete environment within a semiconductor fabrication production facility and further comprising a controller that sends a signal to said actuator responsive to said desired load lock crossover pressure stabilization.

18. The system as in claim 14, wherein said pressure sensor is disposed inside said load lock chamber and detects said ambient pressure when said external load lock door is opened.

19. The system as in claim 14, wherein said semiconductor processing tool comprises one of an etching tool and a deposition tool, said venting system is capable of purging said load lock chamber with an inert gas and said means for determining a desired load lock crossover pressure includes a processor that calculates said desired load lock crossover pressure based on an input relationship between said desired load lock crossover pressure and said detected ambient pressure.

20. The system as in claim 14, wherein said pressure sensor is disposed external said semiconductor processing tool and further comprising a further pressure sensor disposed in said load lock chamber, said further pressure sensor capable of detecting pressure in said load lock chamber.
